(19) United States
(12) Patent Application Publication
(10) Pub. No.: US 2010/0067210 A1
(43) Pub. Date: Mar. 18, 2010

(54) RADIO WAVE SHIELDING CASE

(75) Inventors: Hisashi Sato, Shizuoka (JP); Masanori Sambe, Shizuoka (JP)

Correspondence Address: TUROCY & WATSON, LLP, 127 Public Square, 57th Floor, Key Tower, CLEVELAND, OH, 44114, US

(73) Assignee: TOSHIBA TEC KABUSHIKI KAISHA, Tokyo (JP)

(21) Appl. No.: 12/550,736

(22) Filed: Aug. 31, 2009

(30) Foreign Application Priority Data
Sep. 16, 2008 (JP) 2008-237118

(51) Int. Cl. H05K 9/00

(52) U.S. Cl. 361/818

(57) ABSTRACT

An aspect of the invention is a radio wave shielding case including, a case body having at least a first facet and a second facet connected to the first facet, the first facet including an opening configured to surround a reading facet of a wireless tag reader antenna, a wireless tag slit which is formed in the second facet of the case body and enables a wireless tag to be inserted in the case body so as to face the reading facet of the antenna surrounded by the opening, and a radio wave absorber which covers the opening of the case body and an inner surface except for the wireless tag slit.

### CROSS-REFERENCE TO RELATED APPLICATION

This application is based upon and claims the benefit of priority from prior Japanese Patent Application No. 2008-237118, filed Sep. 16, 2008, the entire contents of which are incorporated herein by reference.

### TECHNICAL FIELD

The present invention relates to a radio wave shielding case which contributes to improvement in accuracy of a wireless tag reader or wireless tag reader writer.

### BACKGROUND

Recently, a small communication medium called wireless tag is developed and is used in various fields including distribution, physical distribution, transportation and security. A wireless tag carries out non-contact communication with a wireless communication device using radio waves and thus can transmit data held in a memory or write received data into the memory. A wireless communication device is generally referred to as wireless tag reader writer. Stationary or portable wireless communication devices are practically used.

A wireless tag reader writer has an antenna such as a planar patch antenna. In the case of reading data of a wireless tag or writing data to the wireless tag, the wireless tag reader writer first transmits a radio wave for tag inquiry from the antenna. The wireless tag which receives this radio wave sends back a response radio wave including an ID for identifying this wireless tag. Thus, the wireless tag reader writer waits for the response radio wave from the wireless tag. Then, as the wireless tag reader writer receives the response radio wave via the antenna, the wireless tag reader writer recognizes the ID included in the response radio wave. At this time, if the ID can be recognized without any collision of radio waves, the wireless tag reader writer transmits a radio wave of a read or write command designating this ID from the antenna. As the wireless tag receives this radio wave, the wireless tag determines whether the ID designated by the command is of this wireless tag or not. If the ID is not of the wireless tag, the command is not executed. If the ID is of the wireless tag, the command is executed.

In this manner, the wireless tag reader writer carries out wireless communication with a wireless tag which responds to an inquiry radio wave and thus reads or writes data. Here, the number of wireless tags responding to an inquiry from the wireless tag reader writer is not necessarily limited to one. All wireless tags existing within a communication area that is reached by radio waves from the antenna can respond. Moreover, the wireless tag reader writer does not necessarily receive a response from the nearest wireless tag to the antenna firstly. Therefore, in an environment where plural wireless tags are placed closely to each other, it is difficult for the wireless tag reader writer to securely carry out wireless communication with a specific wireless tag.

Conventionally, for a wireless tag issuing device which carries a base paper having plural wireless tags mounted thereon at predetermined intervals, thus sequentially delivers the wireless tags to the position where an antenna is installed, then carries out wireless communication with the wireless tags via the antenna and thus writes desired data to the wireless tags, a technique of securely communicating only with a wireless tag that is a wireless communication target is already known.

For example, JP-A-2005-190216 discloses the following technique. That is, the carrying surface of a base paper is made of a metal member and a slit is provided in this metal member. A dielectric member having a convex part is arranged on the lower surface of the metal member and the convex part of the dielectric member is inserted into the slit. Thus, the upper surface of the convex part is made flat with the upper surface of the metal member. Moreover, the antenna of the wireless tag reader writer is arranged below the convex part of the dielectric member and this antenna is housed in a metal case. Thus, if a wireless tag as a wireless communication target is situated above the slit, the wireless tag reader writer carries out wireless communication with the wireless tag via the antenna and writes data to the wireless tag.

JP-A-2005-190216 also discloses a technique of providing a metal case which surrounds a wireless tag and only opens to the direction toward the antenna, at a position where the metal case faces the slit with the base paper inserted between the metal case and the slit.

In the field of distribution, a technique of unit control of articles using wireless tags instead of barcodes is proposed. That is, a wireless tag is attached to each article and information including the PLU code, article name and unit price of the article to which this tag is attached is stored in the memory of this wireless tag. A wireless tag reader writer instead of barcode scanner is connected to a POS (Point Of Sales) terminal as a settlement device. The wireless tag reader writer reads article information from the wireless tag attached to an article purchased by a customer. The POS terminal processes sales data on a unit basis on the basis of the article information read from the wireless tag.

If a wireless tag is used in the field of distribution as described above, it is assumed that accurate information of the article to which the tag is attached is stored in the wireless tag without exception. If information of another article or incorrect information is stored, an error occurs in sales data and the article is sold to the customer for a wrong price. Therefore, credibility of the store is lost.

Meanwhile, many stores offer reduced prices in proper timing, as what is called special sale and time-limited special offer. In offering reduced prices, unit price information in the wireless tag attached to the article needs to be rewritten. For this rewriting, a portable wireless tag reader writer is usually used. The wireless tag reader writer is carried by a person in charge of price change. The person in charge of price change goes to the sales floor, holding the wireless tag reader writer, and rewrites unit price information in the wireless tag attached to a special sale target article to a reduced price or rewrites unit price information in the wireless tag attached to an article for which the special sale period is over, to a regular price. At this time, there is no problem if the information in the wireless tag attached to the special sale target article is securely rewritten. However, in an environment where there is another article near the special sale target article, the information in the wireless tag attached to the special sale target article is not necessarily securely rewritten.

The technique disclosed in JP-A-2005-190216 is applied to a wireless tag issuing device in which wireless tags are regularly arrayed. Therefore, this technique cannot be applied to a wireless tag reader or a wireless tag reader writer in an environment where plural wireless tags can exist irregularly as in a sales floor.

### SUMMARY

An aspect of the invention is a radio wave shielding case comprising, a case body having at least a first facet and a second facet connected to the first facet, the first facet comprising an opening configured to surround a reading facet of a wireless tag reader antenna, a wireless tag slit which is formed in the second facet of the case body and enables a wireless tag to be inserted in the case body so as to face the reading facet of the antenna surrounded by the opening, and a radio wave absorber which covers the opening of the case body and an inner surface except for the wireless tag slit.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing a radio wave shielding case as a first embodiment of the invention;

FIG. 2 is a partial sectional view showing an exemplary application of the radio wave shielding case as the first embodiment;

FIG. 3 is a perspective view showing a radio wave shielding case as a second embodiment of the invention;

FIG. 4 is a partial sectional view showing an exemplary application of the radio wave shielding case as the second embodiment;

FIG. 5 is a schematic view showing essential parts of a radio wave shielding case as a third embodiment of the invention;

FIG. 6 is a schematic view showing a modification of the third embodiment; and

FIG. 7 is a schematic view showing still another modification of the third embodiment.

### DETAILED DESCRIPTION

Hereinafter, embodiments of the invention will be described with reference to the drawings.

### First Embodiment

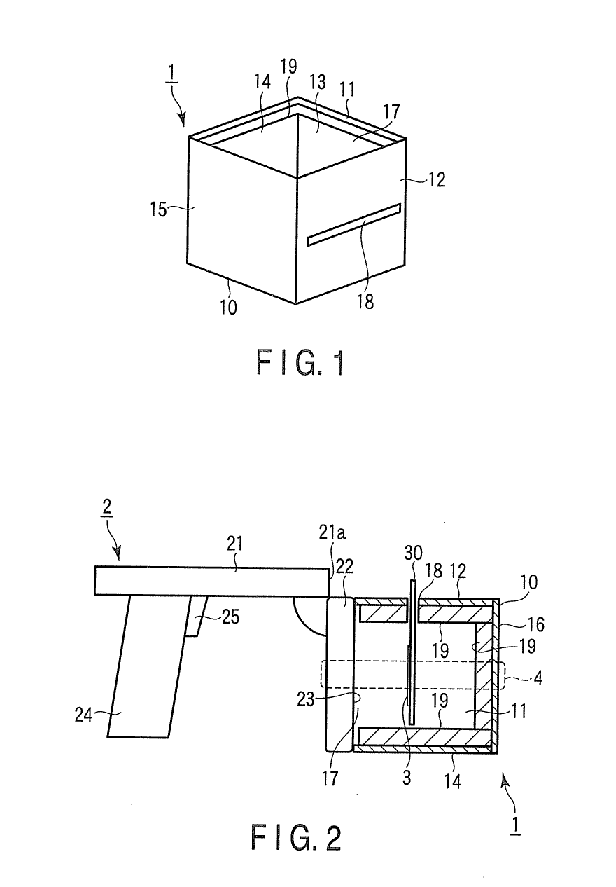

FIG. 1 shows the appearance of a radio wave shielding case 1 according to a first embodiment. FIG. 2 shows an example of applying this radio wave shielding case 1 to a wireless tag reader writer 2.

As shown in the drawings, the radio wave shielding case 1 includes a case body 10, which is a rectangular box having the shape of a substantially regular hexahedron. That is, the case body 10 includes a substantially square first facet 11, substantially square second to fifth facets 12 to 15 of the same size continued in a perpendicular direction from the four sides of the first facet 11, and a substantially square sixth facet 16 joined with each side of the second to fifth facets 12 to 15 that is opposite to the side joined with the first facet 11. All the first to sixth facets 11 to 16 are made of a metal plate.

The case body 10 has a rectangular opening 17 formed substantially over the entire area of the first facet 11. The opening 17 is large enough to surround a reading facet 23 of an antenna 22 in the wireless tag reader writer 2, as shown in FIG. 2. Therefore, the opening 17 does not have to be formed substantially over the entire area of the first facet 11 as long as the opening 17 is large enough to surround the reading facet 23. However, as the opening 17 is formed substantially over the entire area, the size of one facet of the case body 10 can be aligned with the size of the antenna 22.

The wireless tag reader writer 2 includes a gun-type reader writer body 21 and the antenna 22 attached to a distal end part 21a of the reader writer body 21. The antenna 22 is a planar patch antenna and the reading facet 23 is directed forward from the distal end part 21a of the reader writer body 21. As a trigger 25 provided on a grip part 24 of the reader writer body 21 is pulled, the wireless tag reader writer 2 transmits a radio wave for tag inquiry from the reading facet 23 of the antenna 22. In the antenna 22, the communication sensitivity is restrained to a low level on the other facets than the reading facet 23, for example, the lateral facets and the opposite facet to the reading facet 23.

In the case body 10, a slit 18 is formed substantially at a central part of the second facet 12. The slit 18 has a size large enough to enable insertion of a label 30 to which a wireless tag 3 is pasted, and the longitudinal direction of the slit 18 is parallel to the first facet 11, as shown in FIG. 2. The label 30 is made of a non-metal material, for example, paper or resin.

The inner surface of the case body 10 is covered with a radio wave absorber 19 except for the parts where the opening 17 and the slit 18 are formed.

If the radio wave shielding case 1 of such a configuration is applied to the gun-type wireless tag reader writer 2, the user first presses the reading facet 23 of the antenna 22 against the opening 17 formed in the first facet 11 in the state where the case body 10 is turned sideways so that the slit 18 faces upward, as shown in FIG. 2. Then, the reading facet 23 is surrounded by the opening 17.

Next, the user inserts one label 30 to which the wireless tag 3 as a wireless communication target is pasted, from the slit 18. Thus, the wireless tag 3 is arranged facing the reading facet 23 of the antenna 22, as shown in FIG. 2.

In FIG. 2, the wireless tag 3 faces the reading facet 23 of the antenna 22 without the label 30 being present between the wireless tag 3 and the reading facet 23. However, when inserting the label 30 in the slit 18, the user may reverse the side of the label 30. The label 30 is made of a non-metal material, for example, paper or resin. Therefore, the label 30 has no influence on radio waves radiated from the reading facet 23 of the antenna 22. Thus, even if the wireless tag 3 faces the reading facet 23 of the antenna 22 with the label 30 being present between the wireless tag 3 and the reading facet 23, similar effects can be realized.

In this state, the user pulls the trigger 25 of the wireless tag reader writer 2. Thus, a radio wave for tag inquiry is transmitted from the reading facet 23 of the antenna 22. This radio wave is received by the wireless tag 3. As the wireless tag 3 receives the radio wave for tag inquiry, the wireless tag 3 sends back a response radio wave including an ID for identifying this wireless tag 3. This response radio wave is received by the antenna 22. As the wireless tag reader writer 2 receives the response radio wave via the antenna 22, the wireless tag reader writer 2 recognizes the ID included in the response radio wave. At this time, if the ID can be recognized without collision of radio waves or the like, the wireless tag reader writer 2 transmits a radio wave of a read or write command designating that ID from the antenna. As the wireless tag 3 receives this radio wave, the wireless tag 3 determines whether the ID designated by the command is of this wireless tag 3 or not. If the ID is of this wireless tag 3, the command is executed.

Here, in this embodiment, in the state where the reading facet 23 of the antenna 22 is surrounded by the opening 17 of the case body 10, a radio wave for tag inquiry is transmitted from the reading facet 23. No matter which direction this radio wave is propagated in from the reading facet 23, the radio wave passes through the radio wave absorber 19 attached to the inner surface of the case body 10 and is reflected by the second to sixth facets 12 to 16 made of metal plates. Therefore, the radio wave hardly leaks outward from the case body 10. As the radio wave passes through the radio wave absorber 19, the reflected wave from each facet 12 to 16 becomes weak.

Thus, a wireless tag that can receive the radio wave transmitted from the antenna 22 is only the wireless tag 3 pasted to the label 30 inserted from the slit 18. Moreover, since the wireless tag 3 faces the reading facet 23, the receiving sensitivity is very high. Therefore, the wireless tag reader writer 2 can securely recognize the ID of the wireless tag 3 without having any collision with the transmission of the inquiry radio wave. Consequently, even in an environment where other wireless tags can irregularly exist near the outside of the case body 10, it is possible to securely communicate only with a wireless tag as a wireless communication target, that is, only with the wireless tag 3 pasted to the label 30.

In the embodiment, the slit 18 is provided substantially at the center of the second facet 12, but the position where the slit 18 is formed is not limited to this example. The distance to the slit 18 from one side of the second facet 12 joined with the first facet 11 needs to be set in accordance with the type of the antenna 22 that is used. For example, if the antenna 22 having a weak radio wave output is used, the slit is formed at a position closer to the one side joined with the first facet 11 than the center. In this way, communication with the wireless tag 3 as a wireless communication target can be securely carried out.

Thus, plural slits 18 may be formed at shifted positions in order to be able to deal with plural types of antennas. In this case, plural slits may be formed in the same facet, or one to plural slits may be formed in each of the second to fifth facets 12 to 15 extending perpendicularly to the first facet 11.

The distance from another side of the second facet 12 joined with the sixth facet 16 to the slit 18 has the following limitation. That is, in this embodiment, the inner surface of the case body 10 made of a metal plate is covered with the radio wave absorber 19. Therefore, if the distance between the wireless tag 3 inserted from the slit 18 and the radio wave absorber 19 covering the inner surface of the sixth facet 16 is short, the frequency characteristic of the radio wave radiated from the antenna 22 may deteriorate. Therefore, it is not preferable to form the slit 18 closely to the side joined with the sixth facet 16. This frequency characteristic is decided by the frequency of the radio wave and the magnetic permeability of the radio wave absorber 19.

Meanwhile, in the embodiment, the antenna 22 is simply pressed against the opening 17 of the case body 10. However, the antenna 22 pressed against the opening 17 and the case body 10 may be clamped and fixed by a fixing unit such as a rubber band 4, as indicated by the broken line in FIG. 2. In this way, the wireless tag reader writer 2 can be carried in the state where the case body 10 is coupled with the antenna 22. Consequently, the wireless tag reader writer 2 becomes more convenient in an application where the person in charge of price change carries the wireless tag reader writer 2, and in the sales floor, rewrites unit price information of a wireless tag attached to special sale target article to a reduced price or unit price information of a wireless tag attached to an article for which the special sale period is over, to a regular price.

### Second Embodiment

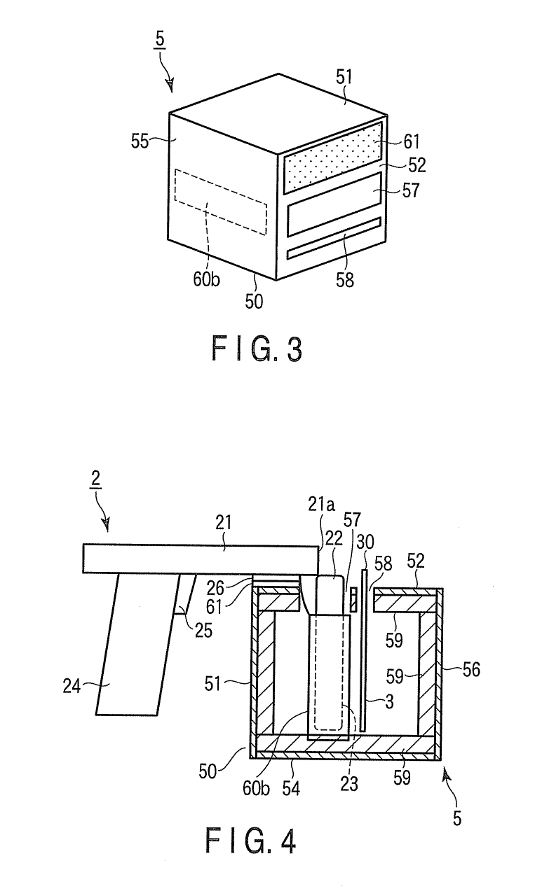

FIG. 3 shows the appearance of a radio wave shielding case 5 according to a second embodiment. FIG. 4 shows an example of applying the radio wave shielding case 5 to the wireless tag reader writer 2. The same parts as in the first embodiments are denoted by the same reference numerals and will not be described further in detail.

As shown in the drawings, the radio wave shielding case 5 includes a case body 50, which is a rectangular box having the shape of a substantially regular hexahedron. That is, the case body 50 includes a substantially square first facet 51, substantially square second to fifth facets 52 to 55 (53 not shown) of the same size continued in a perpendicular direction from the four sides of the first facet 51, and a substantially square sixth facet 66 joined with each side of the second to fifth facets 52 to 55 that is opposite to the side joined with the first facet 51. All the first to sixth facets 51 to 56 are made of a metal plate.

In the case body 50, an antenna slit 57 in which the antenna 22 of the wireless tag reader writer 2 can be inserted is formed substantially at the center of the second facet 52. The longitudinal direction of the antenna slit 57 is parallel to the first facet 51.

In the case body 50, a wireless tag slit 58 in which the label 30 having the wireless tag 3 pasted thereto can be inserted is formed substantially parallel to the antenna slit 57, at a position that is closer to the sixth facet 56 than the center of the second facet 52.

The inner surface of the case body 50 is covered with a radio wave absorber 59 except for the parts where the antenna slit 57 and the wireless tag slit 58 are formed.

On the inner side of the third facet 53 and the inner side of the fifth facet 55 facing the inner side of the third facet 53, which are covered with the radio wave absorber 59, a pair of antenna guides 60a and 60b (60a not shown) for guiding the two lateral sides of the antenna 22 inserted from the antenna slit 57 is attached. Moreover, a second facet fastener 61 which is connected in a removable and attachable manner to a first facet fastener 26 attached to the lower side of the distal end 21a of the body 21 of the reader writer 2, is attached at a position on the second facet 52 that is closer to the first facet 51 than the antenna slit 57. Here, the pair of antenna guide 60a and 60b and the second facet fastener 61 constitute a fixing unit which fixes the antenna 22 inserted from the antenna slit 57 within the case body 50.

If the radio wave shielding case 5 of such a configuration is applied to the gun-type wireless tag reader writer 2, the user first inserts the antenna 22 in the antenna slit 57 in the state where the case body 50 is turned sideways so that the antenna slit 57 and the wireless tag slit 58 face upward, as shown in FIG. 4. Then, the two lateral sides of the antenna 22 are guided by the pair of antenna guides 60a and 60b, and the reading facet 23 of the antenna is positioned in a direction substantially orthogonal to the fourth facet 54 of the case body 50. Also, the first facet fastener 26 provided on the reader writer body 21 and the second facet fastener 61 provided on the second facet 52 of the case body 50 are coupled with each other and the case body 50 is fixed to the reader writer body 21.

Next, the user inserts one label 30 to which the wireless tag 3 as a wireless communication target is pasted, from the wireless tag slit 58. Thus, the wireless tag 3 is arranged facing the reading facet 23 of the antenna 22, as shown in FIG. 4. In FIG. 4, the wireless tag 3 faces the reading facet 23 of the antenna 22 with the label 30 being present between the wireless tag 3 and the reading facet 23. However, there is no problem in reversing the side of the label 30 when inserting the label 30 in the wireless tag slit 58 and thus causing the wireless tag 3 to face the reading facet 23 of the antenna 22 without the label 30 being present between the wireless tag 3 and the reading facet 23.

In this state, the user pulls the trigger 25 of the wireless tag reader writer 2. Thus, a radio wave for tag inquiry is transmitted from the reading facet 23 of the antenna 22. This radio wave is received by the wireless tag 3. As the wireless tag 3 receives the radio wave for tag inquiry, the wireless tag 3 sends back a response radio wave including an ID for identifying this wireless tag 3. This response radio wave is received by the antenna 22. As the wireless tag reader writer 2 receives the response radio wave via the antenna 22, the wireless tag reader writer 2 recognizes the ID included in the response radio wave. At this time, if the ID can be recognized without collision of radio waves or the like, the wireless tag reader writer 2 transmits a radio wave of a read or write command designating that ID from the antenna. As the wireless tag 3 receives this radio wave, the wireless tag 3 determines whether the ID designated by the command is of this wireless tag 3 or not. If the ID is of this wireless tag 3, the command is executed.

Here, in this embodiment, in the state where the reading facet 23 of the antenna 22 is housed in the case body 50, a radio wave for tag inquiry is transmitted from the reading facet 23. No matter which direction this radio wave is propagated in from the reading facet 23, the radio wave passes through the radio wave absorber 19 attached to the inner surface of the case body 50 and is reflected by the first to sixth facets 51 to 56 made of metal plates. Therefore, the radio wave hardly leaks outward from the case body 50. As the radio wave passes through the radio wave absorber 19, the reflected wave from each facet 51 to 56 becomes weak.

Thus, a wireless tag that can receive the radio wave transmitted from the antenna 22 is only the wireless tag 3 pasted to the label 30 inserted from the wireless tag slit 58. Moreover, since the wireless tag 3 faces the reading facet 23, the receiving sensitivity is very high. Therefore, the wireless tag reader writer 2 can securely recognize the ID of the wireless tag 3 without having any collision with the transmission of the inquiry radio wave. Consequently, even in an environment where other wireless tags can irregularly exist near the outside of the case body 50, it is possible to securely communicate only with a wireless tag as a wireless communication target, that is, only with the wireless tag 3 pasted to the label 30.

In the embodiment, the antenna 22 is completely housed within the case body 50. Therefore, communication sensitivity need not be restrained to a low level on the other facets than the reading facet 23, for example, the lateral facets and the facet opposite to the reading facet 23.

In the embodiment, the antenna slit 57 and the wireless tag slit 58 are provided on the same facet, that is, on the second facet 52. However, the antenna slit 57 and the wireless tag slit 58 may be formed separately on two of the second to fifth facets 52 to 55 extending perpendicularly to the first facet 51. However, also in this second embodiment, the distance from the reading facet 23 of the antenna 22 inserted in the antenna slit 57 to the wireless tag 3 inserted in the wireless tag slit 58, and the distance from the wireless tag 3 to the sixth facet 56 have limitations similar to those in the first embodiment.

The fixing unit is not limited to the fixing unit described in the embodiment. For example, magnets may be used instead of the first and second facet fasteners 26 and 61.

### Third Embodiment

In the radio wave shielding cases 1 and 5 according to the first and second embodiments, the inner surface of the case bodies 10 and 50 are covered with the radio wave absorbers 19 and 59, respectively, but diffused reflection by the metal plates constituting the case bodies 10 and 50 cannot be totally eliminated. Therefore, the radio wave radiated from the antenna 22 and the radio wave of diffused reflection overlap each other and a point where the sum of the power of these radio waves becomes zero, that is, so-called null point, may occur. If this null point occurs at the position of the wireless tag 3 inserted from the wireless tag slits 18 and 58, the wireless tag reader writer 2 cannot read data on the wireless tag 3. Such inconvenience can be overcome by changing the distance from the reading facet 23 of the antenna 22 to the wireless tag 3.

Thus, a third embodiment will now be described in which the distance from the reading facet 23 of the antenna 22 to the wireless tag 3 facing the reading facet 23 is variable. In the third embodiment, a case of using the radio wave shielding case 1 according to the first embodiment is described. However, the radio wave shielding case 5 according to the second embodiment can be similarly used.

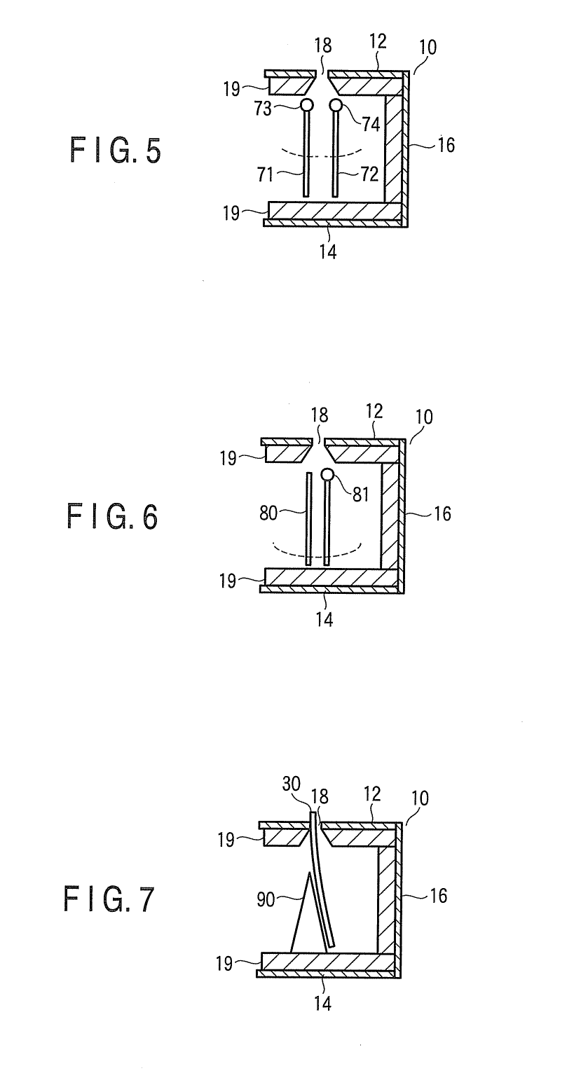

In the third embodiment, a pair of movable guide plates 71 and 72 is provided as a guide unit within the case body 10 from the slit 18 in which the wireless tag 3 is inserted, as shown in FIG. 5. The label 30 with the wireless tag 3, inserted from the slit 18, enters the space between the guide plates 71 and 72. The guide plates 71 and 72 are separate from each other and are rotatable clockwise or counterclockwise in FIG. 5 about one end close to the slit 18 as spindles 73 and 74, respectively.

As these guide plates 71 and 72 are rotated within the case body 10, the wireless tag 3 entering the space between the guide plates 71 and 72 from the slit 18 can be moved in a direction away from or toward the reading facet 23 of the antenna 22.

The guide unit is not limited to the movable guide plates 71 and 72. FIG. 6 and FIG. 7 show other examples of the guide unit. A guide member 80 shown in FIG. 6 is formed by integrating the pair of guide plates 71 and 72. The guide member 80 is rotatable clockwise or counterclockwise in FIG. 6 about one end close to the slit 18 as a spindle 81. The operation of the guide member is similar to that of the pair of guide plates 71 and 72 shown in FIG. 5.

A guide member 90 shown in FIG. 7 has the shape of a triangular prism and its bottom surface is fixed to the inner side of the fourth facet 14 facing the slit 18. As such a guide member 90 is provided, the label 30 with the wireless tag 3 that is inserted from the slit 18 can be curved in a direction away from or toward the reading facet 23 of the antenna 22.

In the above embodiments, the case bodies 10 and 50 are substantially cubic. However, the shape of the case bodies 10 and 50 is not limited to the cubic shape and may be, for example, the shape of a rectangular parallelepiped or a column. The case body 50 described as the second embodiment may also be implemented in a spherical shape.

The wireless tag reader writer 2 that is used is not limited to a gun type and may also be a handy terminal type. Moreover, a radio wave shielding case according to the invention can also be applied to a stationary wireless tag reader writer.

Various other inventions can be made by proper combinations of plural components disclosed in the above embodiments. For example, some of the components described in the embodiments may be deleted. Moreover, components of different embodiments may be combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A radio wave shielding case comprising:
a case body having at least a first facet and a second facet connected to the first facet, the first facet comprising an opening configured to surround a reading facet of a wireless tag reader antenna;
a wireless tag slit which is formed in the second facet of the case body and enables a wireless tag to be inserted in the case body so as to face the reading facet of the antenna surrounded by the opening; and
a radio wave absorber which covers the opening of the case body and an inner surface except for the wireless tag slit.

2. The case according to claim 1, further comprising a fixing unit which fixes the antenna having the reading facet surrounded by the opening, to the case body.

3. A radio wave shielding case comprising:
a case body;
an antenna slit which is formed in one facet of the case body and enables a wireless tag reader antenna to be inserted in the case body; and
a wireless tag slit which is formed in one facet of the case body and enables a wireless tag to be inserted in the case body so as to face a reading facet of the antenna inserted from the antenna slit.

4. The case according to claim 3, further comprising a fixing unit which fixes the antenna inserted from the antenna slit, within the case body.

5. The case according to claim 1, further comprising a guide unit which changes a position of the wireless tag inserted from the wireless tag slit, in a direction away from or toward the reading facet of the antenna.

6. The case according to claim 2, further comprising a guide unit which changes a position of the wireless tag inserted from the wireless tag slit, in a direction away from or toward the reading facet of the antenna.

7. The case according to claim 3, further comprising a guide unit which changes a position of the wireless tag inserted from the wireless tag slit, in a direction away from or toward the reading facet of the antenna.

8. The case according to claim 4, further comprising a guide unit which changes a position of the wireless tag inserted from the wireless tag slit, in a direction away from or toward the reading facet of the antenna.

9. The case according to claim 1, wherein the case body is made of a metal plate.

10. The case according to claim 2, wherein the case body is made of a metal plate.

11. The case according to claim 3, wherein the case body is made of a metal plate.

12. The case according to claim 4, wherein the case body is made of a metal plate.

13. The case according to claim 5, wherein the case body is made of a metal plate.
